(19) United States
(12) Patent Application Publication
(10) Pub. No.: US 2014/0003021 A1
(43) Pub. Date: Jan. 2, 2014

(54) Holding Device for a Portable Communication Device

(71) Applicant: Henryk Bury, Loehne (DE)

(72) Inventor: Henryk Bury, Loehne (DE)

(21) Appl. No.: 13/911,518

(22) Filed: Jun. 6, 2013

(30) Foreign Application Priority Data
Jun. 28, 2012 (DE) 10 2012 012 881.9

(51) Int. Cl. F16M 13/00; H05K 7/02

(52) U.S. Cl. CPC F16M 13/00; H05K 7/02
USPC 361/807; 248/274.1

(57) ABSTRACT

The invention refers to a holding device for a portable communication device, the holding device comprising a mounting device (2) for accommodating the portable communication device, the mounting device comprising a contact surface (4) and at least two holding elements (6), at least one of which is movably arranged along a first movement direction, and at least one motor (14) for moving the at least one movably arranged holding element (6), wherein the mounting device (2) can be put in a release position by moving the at least one movably arranged holding element (6) a first position by means of the motor (14), and in a hold position by moving the at least one movably arranged holding element (6) in a second position by means of the motor (14).

The invention refers to a holding device for a portable communication device, the holding device comprising a mounting device for accommodating the portable communication device, the mounting device comprising a contact surface and at least two holding elements, at least one of which is movably arranged. The invention also refers to a system from a holding device of this type and a corresponding portable communication device.

Nowadays a large variety of holders and holding devices with a mounting device are available, in particular for the use of portable communication devices in vehicles. As a general rule, this type of mounting device comprises a contact surface on which the portable communication device to be accommodated in the mounting device lies, for the most part on its back surface. The mounting device comprises at least two holding elements whose distance from each other can be set, for example, to the width of the portable communication device to be inserted. A portable communication device may be, for example, a mobile telephone, a smartphone or a tablet computer. Of course, other portable communication devices are conceivable. This is known for example from DE 10 2004 062 177 B4. The two holding elements comprise padding on the side facing the portable communication device, creating a friction connection between the holding elements and the inserted portable communication device. In order to achieve a positive-locking connection, it has been suggested to provide the holding elements with indentations which interlock with the corners of the portable communication device to be inserted, for example. This results in a positive-locking connection. However this is not possible with fixed holding elements, so at least one of the holding elements provided must be movably arranged. In this ease, the portable communication device is inserted in the mounting device of the holding device so that its back side lies on the contact surface of the mounting device. The holding elements are then pushed towards each other so that their distance corresponds to a dimension of the portable communication device. This special arrangement of the holding elements results in a positive-locking connection between the holding device and the portable communication device; the portable communication device is thereby held securely in the holder.

For a particularly secure accommodation of the portable communication device in the holding device, it is advantageous if the positive-locking connection is designed in such a way that the portable communication device cannot leave the accommodation device in any direction. This can be achieved by using four holding elements, for example, which are arranged on the four side surfaces of the portable communication device or for example on the four corners of the portable communication device. However, it is a disadvantage that either all of the holding elements must be moved simultaneously from a release position, in which the portable communication device is inserted in the holding device, into a hold position, or only one part of the holding elements is initially moved into the holding position and the portable communication device does not have a positive-locking connection in all directions in the meantime.

When this type of holding device is used in a vehicle, portable communication devices are often not inserted in the holding device until the journey is underway. The driver, who must simultaneously concentrate on traffic and steering their vehicle, has therefore only one free hand to insert the portable communication device. As a result, it is almost impossible to insert the portable communication device in the holding device, which is often upright, and put the different holding elements in the hold position without at least temporarily risking the portable communication device falling out of the holder and then moving around uncontrollably in the vehicle.

The present invention thus aims to propose a holding device into which a portable communication device can be securely, quickly and easily inserted, even with one hand if necessary.

The invention solves the problem at hand via a holding device for a portable communication device that comprises a mounting device for accommodating the portable communication device, which has a contact surface and at least two holding elements, at least one of which is movably arranged along a first movement direction, and at least one motor for moving the at least one movably arranged holding element. The mounting device can be put in a release position by moving the at least one movably arranged holding element in a first position by means of the motor, and in a hold position by moving the at least one movably arranged holding element in a second position by means of the motor. The insertion of a portable communication device in this type of holding device is therefore very simple. The portable communication device is inserted in the mounting device. Even if the contact surface is in an almost vertical position, such as in a vehicle, the portable communication device can be secured in the mounting device with one hand. If the contact surface is not in a vertical position such as this, the portable communication device can be easily inserted in the mounting device. The motor can then be activated with the same hand, which moves the at least one movably arranged holding element along the first movement direction from the first position into the second position, thus moving the mounting device from the release position into the hold position. As soon as the holding elements hold the portable communication device in the mounting device, the portable communication device is prevented from falling out, thereby ensuring a secure hold.

The holding device preferably comprises at least four holding elements, each of which is movably arranged along a first movement direction. Here, the first movement direction can vary greatly from holding element to holding element. The direction in which the respective holding element is movably arranged is the first movement direction for this holding element. In a particularly advantageous arrangement, the holding device comprises four holding elements that are arranged on the four sides of the portable communication device to be inserted.

All four holding elements are preferably movably arranged and are moved towards the portable communication device if the mounting device is moved from the release position into the hold position. The two holding elements arranged on opposite long sides of the portable communication device and the two holding elements arranged on opposite short sides of the portable communication device are consequently moved towards each other in pairs.

It is of course also possible in this configuration to create only two holding elements from four holding elements, each of which is preferably movable along a first movement direction, wherein the two first movement directions for the two movably arranged holding elements are different and in particular are positioned perpendicular to each other. In general, attention should be paid to the fact that the portable communication device can be easily inserted in the mounting device when the mounting device is in the release position, whereas this is not possible when the mounting device is in the hold position.

In the course of this, all movably arranged holding elements can be moved via the one motor, for example, wherein a common gearwheel can be provided so that all holding elements can be moved at the same speed and about the same distance.

Alternatively it is also possible to move the movably arranged holding elements at different times. It is thus conceivable, for example, to initially move two side holding elements and then to move an upper and a lower holding element so that the mounting device is moved into the hold position. In the course of this, attention should be paid to the fact that portable communication devices can have different dimensions and different ratios of length and width; it may therefore be practical for various devices to not move all holding elements about the same distance.

Therefore, at least one of the holding elements preferably comprises a setting device with which a distance between this holding element and another can be set to a dimension of the portable communication device when the mounting device is in the hold position. This type of setting devices consequently makes it possible to set two opposing holding elements in such a way that the distance between them corresponds to the width of the portable communication device, for example, when the mounting device is in the hold position. In this way, the hold device can be universally used for a variety of different portable communication devices with possible different dimensions, without having to use a separate holding device for every portable communication device.

This setting device can preferably comprise a threaded rod with a thread which interlocks with the cogs of a gearwheel. This gearwheel is coupled with the motor, for example, which can set the gearwheel into rotation. A rotation of the gearwheel moves the threaded rod along its longitudinal direction, thereby also moving the holding element fixed on the threaded rod. In contrast, a rotation of the threaded rod only results in a relative movement of the holding element and the gearwheel, so that an adjustment of the distance of, for example, two opposing holding elements can be carried out. In this way, it is consequently possible to very easily set the distance of two holding elements to a dimension of the portable communication device when the mounting device is in the hold position.

At least one of the movably arranged holding elements preferably comprises a spring element which is arranged in such a way that the movement of the holding element from the first position into the second position is at least partially spring-loaded. The spring element can, for example, be arranged on the side of the holding element facing the portable communication device. Should the holding elements now be moved from the first position into the second position in order to move the mounting device from the release position into the hold position, the spring element comes into contact with the portable communication device and is compressed if the holding element is moved further. From this moment, a spring-loaded movement commences. This type of arrangement has the advantage that if the distance of two holding elements is not set exactly to a dimension of the portable communication device when the mounting device is in the hold position, a force is also exerted on the portable communication device, so that the portable communication device is securely held in the mounting device.

Alternatively, the spring element can also be arranged in the holding element in such a way, for example, that the force from the motor is transferred to the holding element by the spring element. Should the holding elements be moved into the second position in these circumstances in order to put the mounting device into the hold position, the holding element comes into contact with the portable communication device, for example, thereby rendering a further movement of the holding element impossible. Nevertheless it s conceivable that due to, for example, defective or inexact settings the motor attempts a further movement of the holding element, thus expanding the spring element arranged between the motor and the holding element. Consequently a spring-loaded movement also commences from this moment; however, this does not involve a movement of the holding element relative to the portable communication device. In this way, an inexact or incorrect setting of the holding elements' position relative to the portable communication device when the mounting device is in the hold position can be compensated for.

The holding device preferably comprises a sensor which is able to register when a portable communication device is inserted in the mounting device. Additionally, the holding device comprises an electric control system that is configured to put the mounting device in the hold position when the sensor registers that a portable communication device is inserted in the mounting device. This type of sensor can be a contact sensor, for example, which is arranged in the contact surface of the mounting device. Should a portable communication device now be inserted in the mounting device, this is registered by the sensor. It sends a corresponding signal to the electric control system which then drives the motor in such a way that it moves the movably arranged holding elements and thus puts the mounting device in the hold position. This arrangement enables a particularly simple insertion of the portable communication device in the holding device. This can be done with one hand, even during the journey in a vehicle, as the portable communication device only has to be held in the mounting device until the movably arranged holding elements have been moved into the relative second position.

In a preferred arrangement, the holding device comprises a control element, wherein the electric control system is configured to move the mounting device from the hold position into the release position by means of the motor when the control element is operated. In place of a mechanical release device often seen in the prior art with which the mounting device is put into the release position, a control element is thus provided here, which is preferably a contact sensor or a proximity sensor. This is preferably arranged on the holding device in such a way that it is easily accessible for a user of the holding device. Should the be a contact sensor, for example, the user of the holding device only has to touch this sensor with a finger or another body part or object to cause the motor to drive the motor so that the mounting device is put in the release position. In this position, the portable communication device can be removed easily from the holding device. However, if the control element is a proximity sensor, actual contact with the sensor is unnecessary. It is sufficient to put or move a body part or object in a predefined area close to the sensor in order to be able to remove the portable communication device from the holding device. In this arrangement, the sensor is preferably arranged in such a way that an accidental release of the sensor is avoided, thus preventing the mounting device of the holding device from inadvertently being put in the release position.

It is preferable if at least one of the holding elements comprises at least one contact element that is movably arranged in a second movement direction, the second movement direction preferably running perpendicular to the first movement direction in which the holding element can be moved.

Holding elements come into contact with the portable communication device via their contact elements, thereby covering a part of the surface of the portable communication device, in particular the side surfaces of the portable communication device. However, depending on the make and model of the portable communication device, important control elements, such as a volume control, or important interfaces, such as cable connections for charging cables or USB cables, can be arranged in exactly the same place. Consequently, these would not be accessible if the portable communication device were in this type of holding device. It is therefore advantageous if at least one of these contact elements can be moved along a second movement direction. This is preferably perpendicular to the first movement direction for this movement to have as great an effect as possible without the portable communication device being in danger of falling out of the mounting device of the holding device. Should the holding element be moved in the transverse direction to the portable communication device, causing the contact elements to lie flat against a long side of the communication device, the relevant contact element can be moved along this long side of the portable communication device until the desired control elements or interfaces are freely accessible.

In particular, should all contact elements be movably arranged in this way, almost every desired interface and every desired control element can be made freely accessible for almost every portable communication device. As a result, it is possible to achieve an optimal arrangement of the holding device for a large variety of portable communication device.

A system according to the invention comprises a holding device as described above, as well as a portable communication device, the portable communication device comprising an electric control system that is configured to send out a signal when a predetermined operation is carried out on the portable communication device. The signal causes the electric control system of the holding device to move the mounting device from the hold position into the release position. In order to configure the electric control system of the portable communication device in this way, software can be made available, for example in the form of an app, which is downloaded and utilized on the portable communication device. In this way, it is also possible to move the mounting device itself from the hold position into the release position by means of an operation on the portable communication device, alternatively or in addition to a control element arranged on the holding device. This can be done by means of contact with a touch screen of the portable communication device, for example, or the input of a numerical code or other such information into the portable communication device. This type of arrangement is particularly advantageous, as the display of the portable communication device must be arranged so that it visible and useable for the driver of a vehicle in which this type of holding device should be deployed.

The mounting device of the holding device can preferably be pivoted about an axis, which is preferably perpendicular to the contact surface of the mounting device. In this process, there are three positions in which the mounting device can be fixed, for example via a locking mechanism, which are particularly advantageous. Modern portable communication devices such as tablet computers or smart phones may comprise various functionalities which require the device to be used in an upright and horizontal position. In order to be able to realize all of these positions with one holding device, it is practical to make the mounting device pivotable, even following the insertion of a portable communication device. In this way, a portable communication device can be inserted upright in the mounting device and directly moved into a horizontal position, for example when is it used as a navigation system or for another purpose. In this process, it is preferable if there are three positions in which the mounting device can be used. These comprise a null position, which allows, for example, a device to be in an upright position, and two further positions; one moved plus 90 degrees relative to the null position and the other minus 90 degrees, in which the device can thus be used in a horizontal position.

It is preferable if the mounting device of the holding device can be additionally pivoted about at least one other axis. By pivoting it about an axis that runs almost vertical in a vehicle, for example, it is possible to arrange a portable communication device in the mounting device so that is can be used by the driver of a vehicle, as well as the passenger. This ensures an optimal position of the portable communication device in the mounting device. If the mounting device can be pivoted about another axis that is perpendicular this second axis and therefore runs, for example, almost horizontally in a vehicle, it is possible to further improve the visibility of the portable communication device and prevent, for example, glaring and thus distracting sunlight from hitting the display of the portable communication device, or at least to limit it. As it can be pivoted about all of these different axes, which are preferably perpendicular to each other, the optimal position of the mounting device relative to the driver and/or passenger of a vehicle can be achieved and the mounting device can be set so that it is optimal for the relevant user. This ensures that in particular the driver of the vehicle needn't to move a lot, particularly their head, in order to see a display of a portable communication device positioned in the mounting device. The distraction from traffic is thereby reduced to a minimum, hence increasing traffic safety.

Modern portable communication devices nowadays often have an inductive charging facility. This means that a battery inside the communication device can be charged without having to establish a plug connection between the communication device and a charging device. This occurs, for example, via inductive charging coils which can be arranged—movably, if required—in the holding device. This renders it possible to arrange one or several inductive charging coils underneath the contact of the mounting device, for example, so that a communication device lying flat on the contact surface can be charged without establishing a plug connection. Should the charging coils be movably arranged inside the mounting device, it is possible to optimally supply different portable communication devices with power by putting the inductive charging coils of the holding device in the relevant optimal position for the communication device placed in it at the time.

In the same way, the connection between the portable communication device and, for example, the antenna of a vehicle can also be established by using the inductive signal transmission. As a result, the portable communication device is able to access an antenna arrangement in the vehicle, for example, without having to utilize a plug connection. In this way, the transmitting power required by the communication device can be reduced, as the antenna arrangement in the vehicle sends the signal out of the vehicle to an antenna located outside.

With the aid of a drawing an embodiment of the present invention will be explained in more detail. What is shown is:

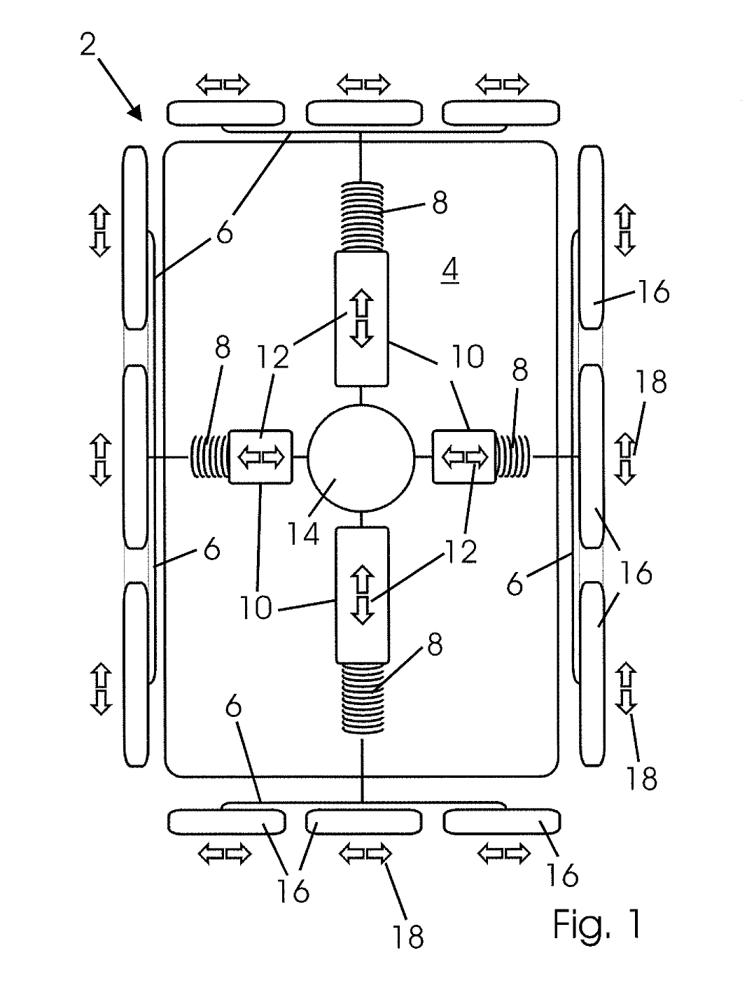

FIG. 1—the schematic view of a holding device according to a first embodiment of the present invention and

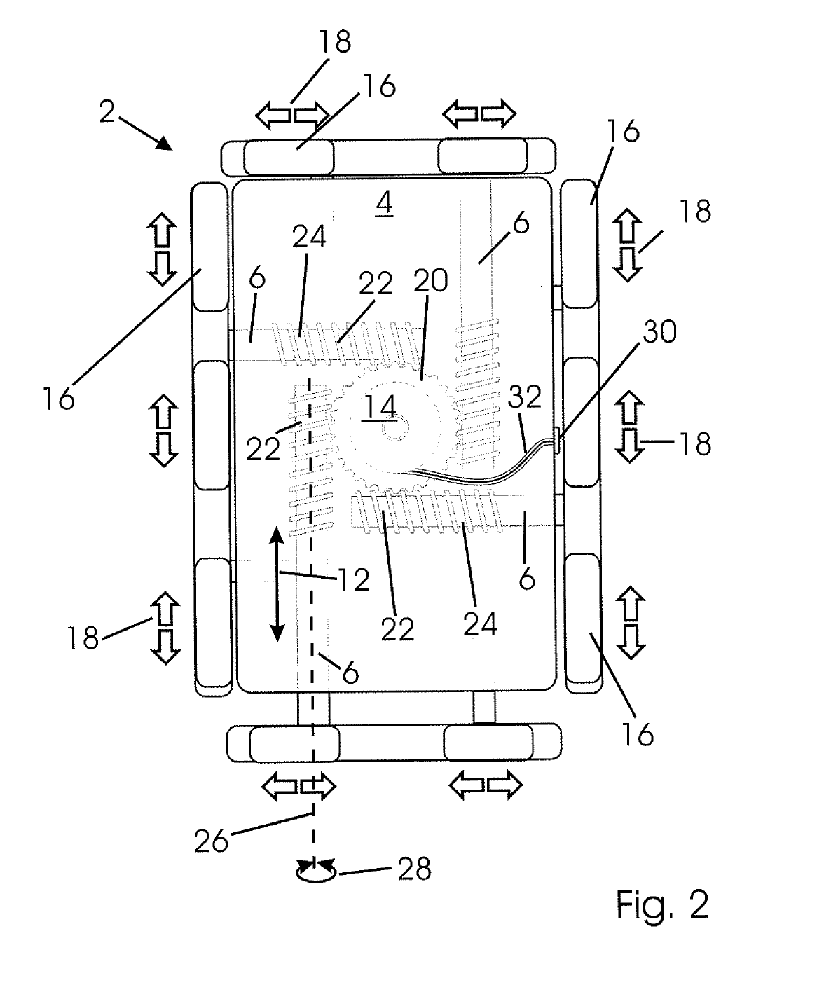

FIG. 2—a further schematic view of a holding device according to a further embodiment of the present invention.

FIG. 1 shows the schematic top view of a holding device according to a first embodiment of the present invention. It comprises a mounting device 2 and a contact surface 4, upon which a portable communication device is positioned, which can be inserted in the mounting device 2, and four holding elements 6. Each holding element 6 is arranged on a movable element 10 via a spring element 8, thereby rendering the holding elements 6 movable as well. In the depiction of the movable elements 10, the first movement direction is indicated by a double arrow 12. The movable elements 10 are coupled with a motor 14, by means of which the movable elements 10, and therefore also the holding elements 6, can be moved along the first movement direction, as indicated by the double arrow 12.

Should the mounting device 2 be put in the release position, the motor 14 ensures that the movable elements 10 and the holding elements 6 fixed to it are moved outwards.

There are three contact elements 16 located on the holding elements 6, which make the real contact with a portable communication device to be inserted in the mounting device 2. A second movement direction, in which the contact elements 16 can be moved, is indicated by a double arrow 18 on each contact element 16. In the course of this, either the contact elements 16 arranged on a holding element 6 can be moved together or each individual contact element 16 is moved in a single movement relative to the rest of the holding element 6. This movement enables available control elements or connections on a portable communication device inserted in the mounting device 2 to remain accessible and useable by preventing a contact element 16 from being arranged in front of these elements.

Should the mounting device 2 shown in FIG. 1 be moved from the release position into the hold position, the motor 14 ensures that the movable elements 10 are moved towards the motor 14. As a result, the holding elements 6 and the contact elements 16 fixed to it are also moved. In the course of this movement the contact elements 16 come into contact with the portable communication device inserted in the mounting device 2. A further movement inwards is then no longer possible, although the motor 14 may attempt to induce another movement and exerts a force on the movable elements 10 and therefore on the holding elements 6. From this moment onwards, the spring elements 8 are expanded. This results in a further movement of the movable elements 10 without the holding elements 6 moving relative to the inserted portable communication device. In the scope of the present invention, this should also be understood to be a spring-loaded movement of the holding element 6, as a movable element 10, which is responsible for the movement of the holding element 6 or causes the movement, is moved further, although the actual holding element 6 and in particular the contact elements 16 are not moved further.

FIG. 2 shows another schematic depiction of a holding device according to an embodiment of the present invention. The mounting device 2 with the contact surface 4 and four holding elements 6 can be recognized. Additionally to the embodiment in FIG. 1, the holding elements 6 can be moved along a first movement direction. For a holding element 6, this is indicated by the double arrow 12. At each outer end of the holding element 6, the contact elements 16 are located, which are movably arranged along the second movement direction, as is depicted by the double arrow 18. The second movement direction is perpendicular to the first movement direction, as is also shown in embodiment in FIG. 1.

The motor 14 is located at the centre of the contact surface, covered by a covering plate if necessary, which is coupled with a gearwheel 20 whose cogs mesh with threads 22 of threaded rods 24, which are part of the respective holding element 6.

Should the motor 14 put the gearwheel 20 into rotation, the four threaded rods 24, and therefore also the contact elements 16 and all the holding elements 6, are moved. As all four threaded rods 24 mesh with the cogs of the same gearwheel 20, all four holding elements 6 are moved at the same speed and along the same route. In the embodiment depicted, a rotation of the gearwheel 20 in a clockwise direction leads to a movement of the holding elements 6 and the contact elements 16 towards the motor 14, moving the contact elements 16 towards a portable communication device inserted in the mounting device and thereby moving the mounting device 2 from the release position into the hold position. A rotation of the gearwheel 6 in an anti-clockwise direction leads to a movement of the holding elements 6 in the opposite direction, increasing the distance between the individual opposing contact elements 16 and thus moving mounting device 2 from the hold position into the release position.

By way of example, a longitudinal axis 26 for a holding element 6 is depicted in FIG. 2 about which the threaded rods 24, corresponding to the double arrow 28, can be rotated. This type of movement causes the respective threaded rods 24 to move relative to the gearwheel 20 connected with the motor 14. This changes the distance between two opposite contact elements 16 and can therefore be set so that this distance corresponds as precisely as possible to a dimension of the portable communication device, such as the length or width, when the mounting device 2 is in the hold position. This enables these distances to be set to the respective dimensions of a portable communication device, so the mounting device 2 and therefore the entire holding device can be used for various portable communication devices.

In addition, FIG. 2 shows a control element 30 that is connected with the electric control system of the holding device via a schematically depicted cable 32. Should the control system 30 be activated, which can be a button, switch, contact sensor or proximity sensor, for example, the electric control system causes the motor 14 to operate in such a way that the mounting device 2 is moved from the hold position into the release position. Alternatively, this can of course also be controlled by a button on the portable communication device if a purpose-made app, i.e. software, is installed and utilized on the portable communication device.

The term motor preferably refers to an electric motor whose energy supply is provided by a battery, for example. Alternatively, it can also be connected to the vehicle's power supply which guarantees a longer service life and means that is it not necessary to change the battery.

### REFERENCE NUMERALS

2 Mounting device
4 Contact surface
6 Holding element
8 Spring element
10 Movable element
12 Double arrow
14 Motor
16 Contact element
18 Double arrow
20 Gearwheel
22 Thread
24 Threaded Rod
26 Longitudinal axis
28 Double arrow
30 Control element
32 Cable

1. A holding device for a portable communication device, the holding device comprising
a mounting device (2) for accommodating the portable communication device, the mounting device (2) comprising
a contact surface (4) and
at least two holding elements (6), at least one of which is movably arranged along a first movement direction and
at least one motor (14) for moving the at least one movably arranged holding
element (6),
wherein the mounting device (2) can be put in a release position by moving the at least one movably arranged holding element (6) in a first position by means of the motor (14), and in a hold position by moving the at least one movably arranged holding element (6) in a second position by means of the motor (14).

2. The holding device according to claim 1, characterized by the fact that the holding device comprises at least four holding elements (6), which are movably arranged along a first movement direction.

3. The holding device according to claim 1, characterized by the fact that at least one of the holding elements (6) comprises a setting device with which a distance between this holding element and another (6) can be set to a dimension of the portable communication device when the mounting device (2) is in the hold position.

4. The holding device according to claim 3, characterized by the fact that the setting device comprises a threaded rod (24) with a thread (22) which interlocks with the cogs of a gearwheel (20).

5. The holding device according to claim 1, characterized by the fact that at least one of the movably arranged holding elements (6) comprises a spring element (8) which is arranged in such a way that the movement of the holding element (6) from the first position into the second position is at least partially spring-loaded.

6. The holding device according to claim 1, characterized by the fact that the holding device comprises a sensor for registering when a portable communication device is inserted in the mounting device (2) and an electric control system that is configured to put the mounting device (2) in the hold position when the sensor registers that a portable communication device is inserted in the mounting device (2).

7. The holding device according to claim 6, characterized by the fact that the holding device comprises a control element (30), wherein the electric control system is configured to move the mounting device (2) from the hold position into the release position by means of the motor (14) when the control element (30) is operated.

8. The holding device according to claim 7, characterized by the fact that the control element (30) is a contact sensor or a proximity sensor.

9. The holding device according to claim 1, characterized by the fact that at least one of the holding elements (6) comprises at least one contact element (16) that is movably arranged in a second movement direction, the second movement direction preferably running perpendicular to the first movement direction in which the holding element (6) can be moved.

10. A system comprising a holding device according to claim 1, as well as a portable communication device, the portable communication device comprising an electric control system that is configured to send out a signal when a predetermined operation is carried out on the portable communication device, the signal causing the electric control system of the holding device to move the mounting device (2) from the hold position into the release position.
